(19) United States
(12) Patent Application Publication
(10) Pub. No.: US 2026/0280526 A1
(43) Pub. Date: Sep. 17, 2026

(54) RADIO-FREQUENCY MODULE AND COMMUNICATION DEVICE

(71) Applicant: Murata Manufacturing Co., Ltd., Nagaokakyo-shi (JP)

(72) Inventors: Natsuhiko HIROSE, Nagaokakyo-shi (JP); Takanori UEJIMA, Nagaokakyo-shi (JP); Nanami YUMURA, Nagaokakyo-shi (JP); Shun SASAKI, Nagaokakyo-shi (JP); Akinori OKANO, Nagaokakyo-shi (JP); Tsubasa UCHIDA, Nagaokakyo-shi (JP)

(73) Assignee: Murata Manufacturing Co., Ltd., Nagaokakyo-shi (JP)

(21) Appl. No.: 19/561,672

(22) Filed: Mar. 10, 2026

(30) Foreign Application Priority Data
Mar. 11, 2025 (JP) 2025-038616

(51) Int. Cl. H03H 9/56; H03H 9/13; H03H 9/17

(52) U.S. Cl. CPC H03H 9/56; H03H 9/133; H03H 9/17

(57) ABSTRACT

A radio-frequency module includes a module substrate having a major surface, an acoustic wave filter disposed on the major surface, and a first electronic component disposed on the major surface. A bonding wire connects the major surface to the first electronic component. A first sealing member encapsulates the first electronic component and the bonding wire 96 but is spaced from the acoustic wave filter. A laminate resin layer has opposite second and third major surfaces, the second major surface 81a being in contact with the major surface, the sealing member, and the acoustic wave filter. A second sealing member contacts with the third major surface and differs in material property from the laminate resin layer and the sealing member.

### CROSS-REFERENCE TO RELATED APPLICATION

This application claims priority to Japanese Patent Application No. 2025-038616, filed on Mar. 11, 2025, the entire contents of which are incorporated herein by reference.

### BACKGROUND

### 1. Field

The present disclosure relates to radio-frequency modules and communication devices.

### 2. Description of the Related Art

Chinese Patent Application Publication No. 114784179 discloses a radio-frequency module having a structure in which a surface acoustic wave filter and electronic components are disposed on a substrate and covered with a film, and a gap is provided between the surface acoustic wave filter and the substrate to maintain the bandpass characteristic of the surface acoustic wave filter, while resin is filled between the electronic components and the substrate to ensure reliability.

### SUMMARY

A radio-frequency module according to an aspect of the present disclosure includes a module substrate having a first major surface, a first acoustic wave filter disposed on the first major surface, a first electronic component disposed on the first major surface, a bonding wire connecting the first major surface to the first electronic component, a first sealing member that is in contact with the first electronic component and the bonding wire and is not in contact with the first acoustic wave filter, a laminate resin layer having a second major surface and a third major surface that are opposite surfaces, the second major surface being in contact with the first major surface, the first sealing member, and the first acoustic wave filter, and a second sealing member disposed in contact with the third major surface, the second sealing member differing from the laminate resin layer and the first sealing member.

### BRIEF DESCRIPTION OF THE DRAWINGS

FIG. 1 illustrates the circuit configuration of a communication device according to an embodiment;

FIGS. 2A and 2B are a plan view and a sectional view of a radio-frequency module according to the embodiment;

FIGS. 3A and 3B are a plan view and a sectional view of a radio-frequency module according to a modification of the embodiment; and

FIG. 4 is a plan view of a collective board formed through the manufacturing process of the radio-frequency module according to the modification of the embodiment.

### DESCRIPTION OF THE EMBODIMENTS

Hereinafter, embodiments of the present disclosure will be described in detail with reference to the drawings. Embodiments described below provide comprehensive or specific examples. Details such as numerical values, shapes, materials, constituent elements, and arrangements and connection modes of the constituent elements provided in the following embodiments are illustrative and are not intended to limit the present disclosure.

The drawings are schematically illustrated with necessary emphasis, omissions, or proportion adjustments to depict the present disclosure and do not necessarily represent exact details; thus, the shapes, positional relationships, and proportions can differ from actual implementations. Identical reference numerals are assigned to substantially the same configuration elements across the drawings, and redundant descriptions of these configuration elements can be omitted or simplified.

In the drawings described below, the x-axis and the y-axis are axes perpendicular to each other in a plane parallel to major surfaces of a module substrate. The z-axis is perpendicular to the major surfaces of the module substrate. The positive side of the z-axis indicates the side located upward, and the negative side of the z-axis indicates the side located downward.

In the following descriptions, the term “connect” includes the case in which one circuit element is directly connected to another circuit element via a connection terminal and/or an interconnect conductor. The term also includes the case in which one circuit element is electrically connected to another circuit element via still another circuit element. The expression “C is connected between A and B” refers to a situation in which one end of C is connected to A, and the other end of C is connected to B, thereby placing C in series in the path connecting A and B. The term “path connecting A and B” refers to a path formed by a conductor that electrically connects A to B.

The term “pass band of a filter” refers to the frequency spectrum that can be passed through the filter and is defined as the frequency range between two frequencies at which the power insertion loss increases by 3 dB from the minimum value.

The term “transmit band” refers to the frequency band used for transmission in a communication device, and the term “receive band” refers to the frequency band used for reception in a communication device. For example, in frequency division duplex (FDD) bands, different frequency bands (an uplink band and a downlink band) are used as the transmit band and the receive band. For example, in time division duplex (TDD) bands, the same frequency band is used for the transmit band and the receive band.

The term “band combination that can be simultaneously communicated” refers to a combination of multiple frequency bands that can be simultaneously transmitted, simultaneously received, or simultaneously transmitted and received, and that are predefined by, for example, standardizing bodies such as the 3rd Generation Partnership Project (3GPP, registered trademark) and the Institute of Electrical and Electronics Engineers (IEEE). Examples of “simultaneous communication” include carrier aggregation (CA), E-UTRAN New Radio-Dual Connectivity (EN-DC), New Radio-Dual Connectivity (NR-DC), and New Radio E-UTRAN-Dual Connectivity (NE-DC).

The term “terminal” refers to a point at which a conductor within an element terminates. When the impedance of a conductor between elements is sufficiently low, the “terminal” is interpreted not only as a single point but also as any point in the conductor between the elements, or as the entire conductor.

The expression “a component is disposed on a substrate” includes the case in which the component is disposed on a major surface of the substrate and the case in which the component is disposed within the substrate. The expression “a component is disposed on a major surface of a substrate” includes the case in which the component is disposed in contact with the major surface of the substrate and also includes the case in which the component is disposed above the major surface without making contact with the major surface (for example, when the component is stacked on another component that is disposed in contact with the major surface). The expression “a component is disposed on a major surface of a substrate” may include the case in which the component is disposed in a depressed portion formed at the major surface. The expression “a component is disposed within a substrate” includes the case in which the component is encapsulated in the substrate. The expression also includes the case in which the component is entirely positioned between the two major surfaces of the substrate but not fully covered by the substrate. The expression further includes the case in which only a portion of the component is disposed within the substrate.

The expression “A is disposed between B and C” refers to a situation in which at least one of the line segments each connecting any given point within B to any given point within C passes through A. The expression “A is disposed closer to C than B” refers to a situation in which the distance between A and C is shorter than the distance between B and C. As used herein, the term “distance between A (B) and C” refers to the length of the shortest line segment (that is, the shortest distance) among the line segments that connect any given point on a surface of A (B) to any given point on a surface of C.

The term “plan view of a module substrate (or a major surface)” refers to a situation in which an object is orthogonally projected in the negative direction along the z-axis onto an xy-plane and viewed. The expression “A overlaps B in the plan view of a module substrate (or a major surface)” means that the region of A orthogonally projected onto an xy-plane overlaps the region of B orthogonally projected onto the xy-plane.

Terms describing relationships between elements, such as “parallel” and “vertical”, terms indicating an element's shape, such as “rectangular”, and numerical ranges are not meant to convey only precise meanings. These terms and numerical ranges denote meanings that are substantially the same, involving, for example, about several percent differences.

When an electronic component A and an electronic component B disposed on a major surface of the substrate are referred to, “(the region) between the electronic component A and the electronic component B” refers to the region surrounded by four line segments: an outer edge of the electronic component A and an outer edge of the electronic component B that oppose each other and are close to each other when the major surface is viewed in plan view, a line segment connecting one end of each of the two outer edges located on the positive side of the extension direction in which the two outer edges extend, and a line segment connecting the other ends of the two outer edges located on the negative side of the extension direction.

### EMBODIMENT

In the known technology described above, since the entire surface of the radio-frequency module is covered with a film, the connection reliability of the electronic components connected to the substrate by bonding wires may be degraded.

In contrast, embodiments are directed to providing a radio-frequency module and a communication device that are configured to suppress degradation in the connection reliability of electronic components connected to a substrate by bonding wires.

### 1. Circuit Configuration of Communication Device 4

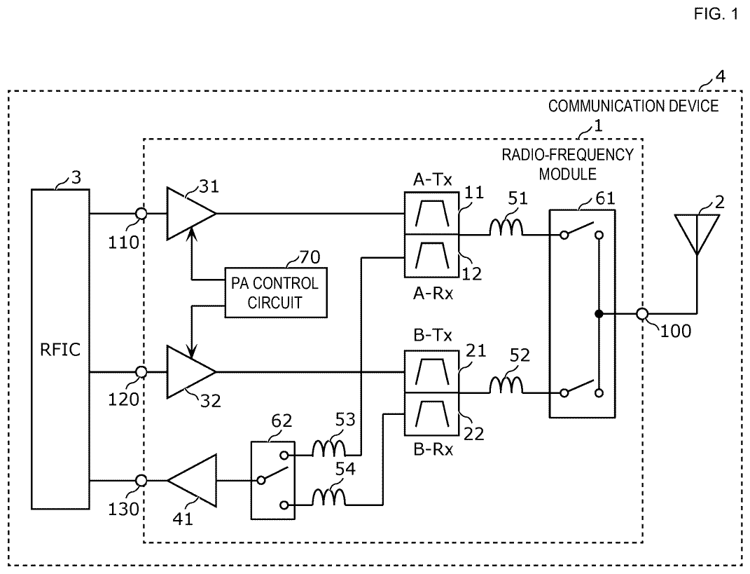

First, the configuration of a communication device 4 according to the present embodiment will be described with reference to FIG. 1. FIG. 1 illustrates the circuit configuration of the communication device 4 according to the present embodiment.

FIG. 1 illustrates an exemplary configuration. The communication device 4 may be implemented using various circuit implementations and circuit techniques. Accordingly, the description of the communication device 4 provided below should not be interpreted as limiting.

The communication device 4 can be used to provide wireless connectivity. For example, the communication device 4 can be installed in user equipment (UE) in cellular networks (also called mobile networks), such as mobile phones, smartphones, tablet computers, and wearable devices. In another example, the communication device 4, when installed, can provide wireless connectivity for Internet of Things (IoT) sensor devices, medical/health-care devices, automobiles, unmanned aerial vehicles (UAVs) (drones), and automated guided vehicles (AGVs). In yet another example, the communication device 4, when installed, can provide wireless connectivity through wireless access points or wireless hotspots.

The communication device 4 includes a radio-frequency module 1, an antenna 2, and a radio frequency integrated circuit (RFIC) 3.

The radio-frequency module 1 is operable to transfer radio-frequency signals between the antenna 2 and the RFIC 3. The circuit configuration of the radio-frequency module 1 will be described later.

The antenna 2 is connected to the radio-frequency module 1. The antenna 2 is operable to receive radio-frequency signals from the radio-frequency module 1 and to transmit the radio-frequency signals to the outside of the communication device 4. The antenna 2 is also operable to receive radio-frequency signals from the outside of the communication device 4 and to supply the radio-frequency signals to the radio-frequency module 1. Part or all of the antenna 2 is not necessarily included in the communication device 4. The communication device 4 may include one or more antennas in addition to the antenna 2.

The RFIC 3 is an example of a signal processing circuit for processing radio-frequency signals. Specifically, the RFIC 3 is operable to process, for example by up-conversion, transmit signals input from a baseband integrated circuit (BBIC) and to output the radio-frequency transmit signals generated by the signal processing to the radio-frequency module 1. The RFIC 3 is also operable to process, for example by down-conversion, radio-frequency receive signals input through the radio-frequency module 1 and to output the receive signals generated by the signal processing to the BBIC. The RFIC 3 may include a control unit for controlling components included in the radio-frequency module 1, such as switches and amplifiers. The function of the RFIC 3 as the control unit may be partially or entirely configured outside the RFIC 3; for example, the function of the RFIC 3 as the control unit may be partially or entirely configured in the BBIC or the radio-frequency module 1.

### 2. Circuit Configuration of Radio-Frequency Module 1

Next, the circuit configuration of the radio-frequency module 1 according to the embodiment will be described with reference to FIG. 1. The radio-frequency module 1 may be implemented using various circuit implementations and circuit techniques. Accordingly, the description of the radio-frequency module 1 provided below should not be interpreted as limiting.

The radio-frequency module 1 includes acoustic wave filters 11, 12, 21, and 22, power amplifiers 31 and 32, a low-noise amplifier 41, switches 61 and 62, inductors 51, 52, 53, and 54, a power amplifier (PA) control circuit 70, an antenna connection terminal 100, radio-frequency input terminals 110 and 120, and a radio-frequency output terminal 130.

The antenna connection terminal 100 is an external connection terminal of the radio-frequency module 1. The antenna connection terminal 100 is a terminal for supplying radio-frequency signals to the antenna 2 and for receiving radio-frequency signals from the antenna 2. The antenna connection terminal 100 is connected to the antenna 2 outside the radio-frequency module 1 and to the switch 61 inside the radio-frequency module 1.

The radio-frequency input terminals 110 and 120 are external connection terminals of the radio-frequency module 1 for receiving radio-frequency signals from the RFIC 3. The radio-frequency input terminals 110 and 120 are connected to the RFIC 3 outside the radio-frequency module 1 and are respectively connected to the power amplifiers 31 and 32 inside the radio-frequency module 1.

The radio-frequency output terminal 130 is an external connection terminal of the radio-frequency module 1 for supplying radio-frequency signals to the RFIC 3. The radio-frequency output terminal 130 is connected to the RFIC 3 outside the radio-frequency module 1 and is connected to the low-noise amplifier 41 inside the radio-frequency module 1.

The acoustic wave filter 11 is an example of a first acoustic wave filter. The acoustic wave filter 11 is a band pass filter having a pass band that includes the transmit band (A-Tx) of a band A. The acoustic wave filter 11 is operable to pass signals within the transmit band of the band A and to attenuate signals outside the transmit band of the band A. One end of the acoustic wave filter 11 is connected to one end of the power amplifier 31, and the other end of the acoustic wave filter 11 is connected to the switch 61 via the inductor 51.

The acoustic wave filter 12 is an example of a first acoustic wave filter. The acoustic wave filter 12 is a band pass filter having a pass band that includes the receive band (A-Rx) of the band A. The acoustic wave filter 12 is operable to pass signals within the receive band of the band A and to attenuate signals outside the receive band of the band A. One end of the acoustic wave filter 12 is connected to the switch 61 via the inductor 51, and the other end of the acoustic wave filter 12 is connected to the switch 62 via the inductor 53. The acoustic wave filter 12 is not necessarily included in the radio-frequency module 1.

The acoustic wave filter 21 is an example of a first acoustic wave filter. The acoustic wave filter 21 is a band pass filter having a pass band that includes the transmit band (B-Tx) of a band B. The acoustic wave filter 21 is operable to pass signals within the transmit band of the band B and to attenuate signals outside the transmit band of the band B. One end of the acoustic wave filter 21 is connected to one end of the power amplifier 32, and the other end of the acoustic wave filter 21 is connected to the switch 61 via the inductor 52. The acoustic wave filter 21 is not necessarily included in the radio-frequency module 1.

The acoustic wave filter 22 is an example of a first acoustic wave filter. The acoustic wave filter 22 is a band pass filter having a pass band that includes the receive band (B-Rx) of the band B. The acoustic wave filter 22 is operable to pass signals within the receive band of the band B and to attenuate signals outside the receive band of the band B. One end of the acoustic wave filter 22 is connected to the switch 61 via the inductor 52, and the other end of the acoustic wave filter 22 is connected to the switch 62 via the inductor 54. The acoustic wave filter 22 is not necessarily included in the radio-frequency module 1.

The acoustic wave filters 11, 12, 21, and 22 are not necessarily band pass filters. One, some, or all of the acoustic wave filters 11, 12, 21, and 22 may be band-elimination filters, high pass filters, low pass filters, or any combination thereof.

The band A is an example of a first band. The band A is an FDD band, a TDD band, or a supplementary uplink (SUL) band. The band B is an example of a second band. The band B is an FDD band, a TDD band, or an SUL band. The band A and the band B are a band combination that can be simultaneously communicated.

The power amplifier 31 is an example of a first electronic component. The power amplifier 31 is connected between the radio-frequency input terminal 110 and the acoustic wave filter 11. The power amplifier 31 is operable to amplify transmit signals of the band A using power supplied by a power supply. The power amplifier 32 is an example of a first electronic component. The power amplifier 32 is connected between the radio-frequency input terminal 120 and the acoustic wave filter 21. The power amplifier 32 is operable to amplify transmit signals of the band B using power supplied by a power supply. The power amplifier 32 is not necessarily included in the radio-frequency module 1.

The low-noise amplifier 41 is connected between the radio-frequency output terminal 130 and the switch 62. The low-noise amplifier 41 is operable to amplify receive signals of the band A and receive signals of the band B using power supplied from a power supply. The low-noise amplifier 41 may be configured to include a first low-noise amplifier configured to amplify receive signals of the band A and a second low-noise amplifier configured to amplify receive signals of the band B. In this case, the switch 62 is unnecessary, and the first low-noise amplifier is connected to the acoustic wave filter 12 via the inductor 53, while the second low-noise amplifier is connected to the acoustic wave filter 22 via the inductor 54. The low-noise amplifier 41 is not necessarily included in the radio-frequency module 1.

One end of the inductor 51 is connected to the switch 61, and the other end of the inductor 51 is connected to the acoustic wave filters 11 and 12. The inductor 51 is an element configured to provide impedance matching between the antenna 2 and the switch 61, and the acoustic wave filters 11 and 12. One end of the inductor 52 is connected to the switch 61, and the other end of the inductor 52 is connected to the acoustic wave filters 21 and 22. The inductor 52 is an element configured to provide impedance matching between the antenna 2 and the switch 61, and the acoustic wave filters 21 and 22.

One end of the inductor 53 is connected to the acoustic wave filter 12, and the other end of the inductor 53 is connected to the switch 62. The inductor 53 is an element configured to provide impedance matching between the acoustic wave filter 12, and the switch 62 and the low-noise amplifier 41. One end of the inductor 54 is connected to the acoustic wave filter 22, and the other end of the inductor 54 is connected to the switch 62. The inductor 54 is an element configured to provide impedance matching between the acoustic wave filter 22, and the switch 62 and the low-noise amplifier 41.

The inductors 51 to 54 are not necessarily provided in series in the signal paths, but may be connected between the signal paths and ground. Each of the inductors 51 to 54 may be implemented as an inductor, a capacitor, or a combination thereof. The inductors 51 to 54 may be omitted from the radio-frequency module 1.

The switch 61 is an antenna switch connected between the antenna connection terminal 100 and the acoustic wave filters 11, 12, 21, and 22. Specifically, the switch 61 includes a common terminal, a first selection terminal, and a second selection terminal. The common terminal is connected to the antenna connection terminal 100. The first selection terminal is connected to the acoustic wave filters 11 and 12 via the inductor 51. The second selection terminal is connected to the acoustic wave filters 21 and 22 via the inductor 52. The switch 61 is operable to, for example, based on a digital control signal supplied by the RFIC 3, selectively connect and disconnect the antenna connection terminal 100 to and from the acoustic wave filters 11 and 12 and selectively connect and disconnect the antenna connection terminal 100 to and from the acoustic wave filters 21 and 22. The switch 61 is not necessarily included in the radio-frequency module 1.

The switch 62 is connected between the acoustic wave filters 12 and 22 and the low-noise amplifier 41. Specifically, the switch 62 includes a common terminal, a first selection terminal, and a second selection terminal. The common terminal is connected to the input end of the low-noise amplifier 41. The first selection terminal is connected to the acoustic wave filter 12 via the inductor 53. The second selection terminal is connected to the acoustic wave filter 22 via the inductor 54. The switch 62 is operable to, for example, based on a digital control signal supplied by the RFIC 3, selectively connect and disconnect the acoustic wave filter 12 to and from the low-noise amplifier 41 and selectively connect and disconnect the acoustic wave filter 22 to and from the low-noise amplifier 41. The switch 62 is not necessarily included in the radio-frequency module 1.

The low-noise amplifier 41 and at least one of the switches 61 and 62 may be included in a single semiconductor component. For example, a silicon single crystal (Si), gallium nitride (GaN), or silicon carbide (SiC) may be used as the material for the semiconductor component. In this case, part or all of the switch included in the semiconductor component may be implemented using a field-effect transistor (FET).

The PA control circuit 70 is an example of a first electronic component. The PA control circuit 70 is operable to control the power amplifiers 31 and 32. Specifically, the PA control circuit 70, for example, based on a digital control signal supplied from the RFIC 3, outputs control signals to the power amplifiers 31 and 32 for controlling the power amplifiers 31 and 32. Such control signals, for example, control the bias currents supplied to the power amplifiers 31 and 32. The PA control circuit 70 is not necessarily included in the radio-frequency module 1.

### 3. Mounting Configuration of Radio-Frequency Module 1

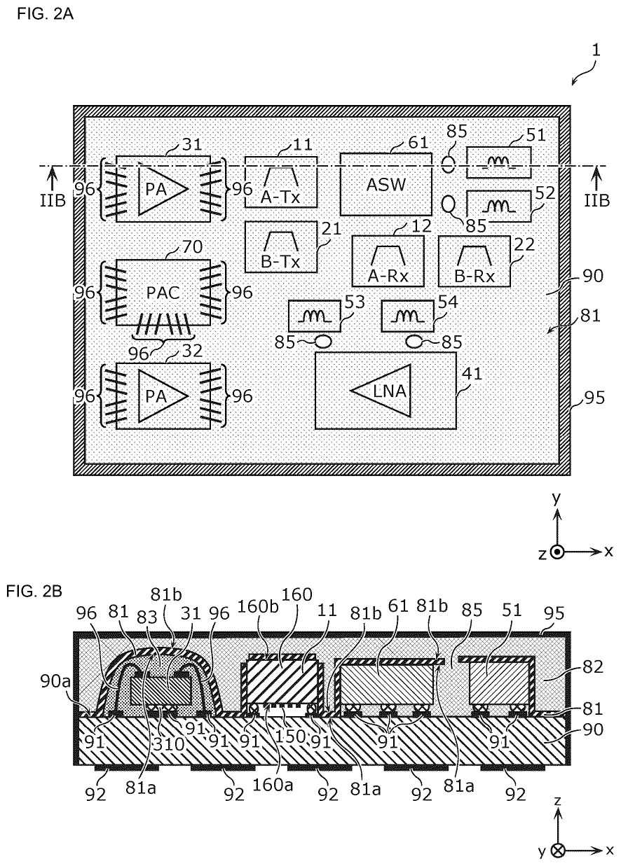

Next, the mounting configuration of the radio-frequency module 1 having the circuit configuration described above will be described with reference to the drawings. FIGS. 2A and 2B are a plan view and a sectional view of the radio-frequency module 1 according to the embodiment. FIG. 2A is a cutaway view of a major surface 90a of a module substrate 90 as viewed from the positive side of the z-axis. FIG. 2B is a sectional view taken along line IIB-IIB in FIG. 2A.

For ease of understanding the positional relationship between electronic components, FIG. 2A omits illustration of a sealing member 83, which covers the power amplifiers 31 and 32 and the PA control circuit 70, a sealing member 82, which covers the electronic components, and a shield layer 95, which covers the sealing member 82. In FIG. 2A, each electronic component is labeled with a corresponding reference label, but the actual electronic components are not necessarily labeled with such reference labels.

FIG. 2 illustrates an exemplary layout. The radio-frequency module 1 may be implemented using various circuit implementations and circuit techniques. Accordingly, the description of the radio-frequency module 1 provided below should not be interpreted as limiting.

In addition to the electronic components illustrated in FIG. 1, the radio-frequency module 1 includes the module substrate 90, a laminate resin layer 81, the sealing members 82 and 83, the shield layer 95, planar electrodes 91, external connection electrodes 92, and bonding wires 96.

The module substrate 90 has the major surface 90a (a first major surface). Circuit elements such as wires and via-conductors are formed in and/or on the module substrate 90. The module substrate 90 may be, for example, a substrate including a ceramic body formed of a stack of dielectric layers co-fired at a low temperature (LTCC: low temperature co-fired ceramics), a substrate including a ceramic body formed of a stack of dielectric layers co-fired at a high temperature (HTCC: high temperature co-fired ceramics), a component-embedded substrate, a substrate including redistribution layers (RDL), or a printed-circuit board. However, these examples should not be interpreted as limiting.

The laminate resin layer 81 has a major surface 81a (a second major surface) and a major surface 81b (a third major surface) that are opposite surfaces, as illustrated in FIG. 2B. The major surface 81a is in contact with the major surface 90a, the sealing member 83, the acoustic wave filters 11, 12, 21, and 22, the low-noise amplifier 41, the switch 61, and the inductors 51 to 54. The laminate resin layer 81 is not in contact with the power amplifiers 31 and 32, the PA control circuit 70, or the bonding wires 96.

In FIG. 2B, the major surfaces 81a and 81b are each illustrated as consisting of multiple connected planes; however, in the actual major surfaces 81a and 81b, the boundaries connecting the planes are rounded, and the actual major surfaces 81a and 81b are both curved. In the present embodiment, the laminate resin layer 81 covers electronic components other than the power amplifiers 31 and 32 and the PA control circuit 70.

The laminate resin layer 81, for example, is formed of epoxy resin and has a thickness of 20 to 200 μm. The elastic modulus of the laminate resin layer 81 is, for example, 5000 MPa (at −40° C.), 600 MPa (at 25° C.), and 4 MPa (at 150° C.). In the manufacturing process of the radio-frequency module 1, a sheet of epoxy resin is placed on the major surface 90a of the module substrate 90 on which electronic components are mounted, and the electronic components and the sheet are bonded to each other by heating while the shape of the sheet is maintained.

The sealing member 82 is an example of a second sealing member. The sealing member 82 is disposed in contact with the major surface 81b of the laminate resin layer 81. The sealing member 82 differs from the laminate resin layer 81 in at least one of a shape and physical properties.

The sealing member 83 is an example of a first sealing member. The sealing member 83 is disposed in contact with the power amplifiers 31 and 32, the PA control circuit 70, and the bonding wires 96, but not in contact with the acoustic wave filter 11, 12, 21, or 22. The sealing member 83 differs from the laminate resin layer 81 and the sealing member 82 in at least one of a shape and physical properties.

The sealing members 82 and 83 are formed of, for example, epoxy resin. The elastic modulus of the sealing members 82 and 83 is, for example, 22 GPa (at temperatures lower than the glass transition temperature Tg) and 0.2 GPa (at temperatures higher than Tg). The glass transition temperature Tg of the sealing member 82 is, for example, 125° C. For example, the first sealing member 83 may be formed from a liquid or gel material (e.g., potting resin) having a low viscosity during application to prevent deformation of the bonding wire 96. Conversely, the laminate resin layer 81 may be a pre-formed solid resin sheet (e.g., a semi-cured epoxy sheet) possessing sufficient rigidity to bridge the gap over the acoustic wave filter 11 without sagging.

The following describes an example of the manufacturing process of the radio-frequency module 1.

(1) First, liquid, gel, or powder epoxy resin is applied to the power amplifiers 31 and 32 and the PA control circuit 70 on the module substrate 90 on which the electronic components are mounted, and heat is applied to melt the epoxy resin, thereby forming the sealing member 83 to cover the power amplifiers 31 and 32 and the PA control circuit 70. The molten epoxy resin does not reach the acoustic wave filter 11, 12, 21, or 22.

(2) Next, a sheet of laminate resin is placed on the entire major surface 90a, powder epoxy resin is applied to the sheet of laminate resin, and heat is applied to soften the sheet of laminate resin and melt the powder epoxy resin, thereby bonding the sheet of laminate resin (the laminate resin layer 81) and the molten epoxy resin (the sealing member 82).

The laminate resin layer 81 and the sealing members 82 and 83 can be distinguished by measuring the elastic modulus. The interface between the laminate resin layer 81 and the sealing members 82 and 83 can be identified by obtaining microscopic images of the cross-sections of the radio-frequency module 1.

The shield layer 95 is a conductive film disposed to cover the sealing member 82, and is, for example, a metal film. The potential of the shield layer 95 is set to ground.

The planar electrodes 91 are electrodes disposed on the major surface 90a to fix the electronic components to the module substrate 90 and to make electrical connections with the electronic components. The planar electrodes 91 are joined to the electronic components via bumps, solder joints, or bonding wires.

The external connection electrodes 92 are electrodes disposed on the major surface opposite the major surface 90a of the module substrate 90 to fix the radio-frequency module 1 to a mother substrate and to make electrical connections between the radio-frequency module 1 and the mother substrate.

As illustrated in FIG. 2A, the acoustic wave filters 11, 12, 21, and 22, the inductors 51 to 54, the low-noise amplifier 41, the switch 61, the power amplifiers 31 and 32, and the PA control circuit 70 are disposed on the major surface 90a. The switch 62 may be included in a semiconductor component that includes the low-noise amplifier 41. At least one of the electronic components other than the acoustic wave filter 11 and the power amplifier 31 may be disposed on the major surface opposite the major surface 90a of the module substrate 90.

The power amplifier 31 is connected to the planar electrode 91 via the bonding wires 96. The power amplifier 31 and the bonding wires 96 are in contact with the sealing member 83 and are not in contact with the laminate resin layer 81. In the manufacturing process of the radio-frequency module 1, the sealing member 83 is in a liquid or gel form, and the laminate resin layer 81 is in a solid form. As a result, if the bonding wires 96 are brought into contact with the laminate resin layer 81 in a solid form during the manufacturing process, the bonding wires 96 can be deformed by a force applied by the laminate resin layer 81. This may degrade the reliability of the connection between the power amplifier 31 and the planar electrodes 91. In contrast, in the manufacturing process according to the present embodiment, the bonding wires 96 are not brought into contact with the laminate resin layer 81, but instead are brought into contact with the sealing member 83 in a molten state. Accordingly, the force applied to the bonding wires 96 by the sealing member 83 is relatively small. As a result, the bonding wires 96 are not deformed, so the reliability of the connection between the power amplifier 31 and the planar electrodes 91 is not degraded.

The power amplifier 32 is connected to the planar electrode 91 via the bonding wires 96. The power amplifier 32 and the bonding wires 96 are in contact with the sealing member 83 and are not in contact with the laminate resin layer 81. As a result, similarly to the bonding wires 96 connected to the power amplifier 31, the bonding wires 96 connected to the power amplifier 32 are not deformed, so the reliability of the connection between the power amplifier 32 and the planar electrodes 91 is not degraded.

At least one of the power amplifiers 31 and 32 may be disposed in contact with the planar electrodes 91 (the major surface 90a) via long bumps 310. This connection method increases the contact area between the power amplifier 31 or 32 and the planar electrodes 91, and thus the heat dissipation from the power amplifier 31 or 32 to the module substrate 90 is improved.

The PA control circuit 70 is connected to the planar electrode 91 via the bonding wires 96. The PA control circuit 70 and the bonding wires 96 are in contact with the sealing member 83 and are not in contact with the laminate resin layer 81. As a result, similarly to the bonding wires 96 connected to the power amplifier 31, the bonding wires 96 connected to the PA control circuit 70 are not deformed, so the reliability of the connection between the PA control circuit 70 and the planar electrodes 91 is not degraded.

The acoustic wave filter 11 includes an interdigital transducer (IDT) electrode 150 and a piezoelectric substrate 160, as illustrated in FIG. 2B.

The IDT electrode 150 is an example of a first IDT electrode. The IDT electrode 150 is disposed on a major surface 160a of the piezoelectric substrate 160. The IDT electrode 150 has multiple first electrode fingers and multiple second electrode fingers, and a first busbar electrode and a second busbar electrode. The first electrode fingers are arranged parallel to each other, and the second electrode fingers are arranged parallel to each other. The first electrode fingers and the second electrode fingers are arranged parallel to each other to be interdigitated with each other. The first busbar electrode is disposed to connect one end of each of the first electrode fingers. The first busbar electrode extends in a direction that intersects the extension direction in which the first electrode fingers extend. The second busbar electrode is disposed to connect one end of each of the second electrode fingers. The second busbar electrode extends in a direction that intersects the extension direction in which the second electrode fingers extend. The first busbar electrode and the second busbar electrode are disposed opposite each other with the first electrode fingers and the second electrode fingers interposed therebetween. The other end of each of the first electrode fingers opposes the second busbar electrode, and the other end of each of the second electrode fingers opposes the first busbar electrode. A reflector electrode may be disposed adjacent to the IDT electrode 150 in a direction perpendicular to the extension direction of the first electrode fingers and the second electrode fingers.

The piezoelectric substrate 160 is piezoelectric. The piezoelectric substrate 160 has a major surface 160a (a fourth major surface) and a major surface 160b (a fifth major surface) that oppose each other. The piezoelectric substrate 160 is, for example, a piezoelectric single-crystal substrate and is formed of lithium tantalate, lithium niobate, quartz, or gallium nitride. The piezoelectric substrate 160 is in contact with the major surface 81a of the laminate resin layer 81.

The IDT electrode 150 is connected to a wiring electrode formed on the major surface 160a, and is connected to the planar electrodes 91 via bumps joined to the wiring electrode. Because the IDT electrode 150 is connected to the planar electrodes 91 via bumps and the side surfaces of the piezoelectric substrate 160 are in contact with the laminate resin layer 81, a gap is formed between the IDT electrode 150 and the major surface 90a. In other words, the IDT electrode 150 opposes the major surface 90a with a gap interposed therebetween.

The piezoelectric substrate 160 may include a piezoelectric layer, a dielectric layer, and a support substrate instead of being a piezoelectric single-crystal substrate. In this case, the piezoelectric substrate 160 includes the major surface 160a, the piezoelectric layer, the dielectric layer, the support substrate, and the major surface 160b that are arranged in this order.

The piezoelectric layer may be formed of lithium tantalate or a material mainly composed of lithium tantalate. The piezoelectric layer may be formed of a material such as lithium niobate, quartz, or gallium nitride.

The dielectric layer includes, for example, a low acoustic velocity layer and a high acoustic velocity layer. The low acoustic velocity layer and the high acoustic velocity layer are arranged in this order from the piezoelectric layer to the support substrate. The bulk wave velocity in the low acoustic velocity layer is lower than the bulk wave velocity in the piezoelectric layer. The bulk wave velocity in the high acoustic velocity layer is higher than the bulk wave velocity in the low acoustic velocity layer. It is sufficient that the dielectric layer includes at least one of the low acoustic velocity layer and the high acoustic velocity layer.

The low acoustic velocity layer contains at least one of silicon oxide and silicon oxynitride. The low acoustic velocity layer may be formed of a dielectric material such as silicon oxide, silicon oxynitride, glass, lithium oxide, tantalum pentoxide, or a compound including silicon oxide and fluorine, carbon, or boron, or a material mainly composed of any of the above materials.

The high acoustic velocity layer contains silicon nitride. The high acoustic velocity layer may be formed of silicon nitride, silicon oxynitride, amorphous silicon, polysilicon, aluminum oxide, or aluminum nitride, or a material mainly composed of any of the above materials.

The dielectric layer may include, in place of the low acoustic velocity layer and the high acoustic velocity layer, an energy confining layer including a low acoustic impedance layer having a relatively low acoustic impedance and a high acoustic impedance layer having a relatively high acoustic impedance, the low acoustic impedance layer and the high acoustic impedance layer being alternately stacked. Additionally, a gap may be formed in the piezoelectric substrate 160 in place of part or all of the dielectric layer.

The support substrate is a substrate that supports the IDT electrode 150, the piezoelectric layer, and the dielectric layer. The support substrate may be formed of, for example, a piezoelectric material such as silicon, aluminum nitride, aluminum oxide, lithium niobate, or quartz; a ceramic such as sapphire, magnesia, silicon nitride, silicon carbide, zirconia, cordierite, mullite, steatite, or forsterite; a dielectric material such as diamond or glass; a semiconductor such as gallium nitride; a resin; or a material mainly composed of any of the above materials.

In the acoustic wave filter 11, an insulating layer may be disposed between the major surface 160a and the IDT electrode 150. An insulating layer may be disposed to cover the IDT electrode 150.

The acoustic wave filters 12, 21, and 22 have the same structure as the acoustic wave filter 11. In the acoustic wave filters 12, 21, and 22, an IDT electrode is connected to a wiring electrode formed on a fourth major surface of a piezoelectric substrate, and is connected to the planar electrodes 91 via bumps joined to the wiring electrode. Because the IDT electrode is connected to the planar electrodes 91 via bumps and the side surfaces of the piezoelectric substrate are in contact with the laminate resin layer 81, a gap is formed between the IDT electrode and the major surface 90a.

As illustrated in FIG. 2B, corner portions of the acoustic wave filter 11 at which the side surfaces of the piezoelectric substrate 160 meet the major surface 160b may be directly in contact with the sealing member 82, with the laminate resin layer 81 not interposed therebetween.

The acoustic wave filter 11 is fixed to the module substrate 90 only by bumps, since a gap needs to be formed between the IDT electrode 150 and the major surface 90a. In contrast, because corner portions of the acoustic wave filter 11 are directly in contact with the sealing member 82, the fixing strength of the acoustic wave filter 11 on the module substrate 90 is improved, thereby increasing reliability, and the mechanical strength of the radio-frequency module 1 is improved.

Any electronic component among the low-noise amplifier 41, the switch 61, and the inductors 51 to 54 may be connected to the planar electrodes 91 via the bonding wires 96. In this case, the electronic component corresponds to a first electronic component that is in contact with the sealing member 83 and is not in contact with the laminate resin layer 81.

Any electronic component among the power amplifiers 31 and 32 and the PA control circuit 70 may be connected to the planar electrodes 91 via bumps instead of via bonding wires 96. In this case, the electronic component is in contact with the laminate resin layer 81.

The major surface 160b (top surface) of the piezoelectric substrate 160 of the acoustic wave filter 11 may be in contact with the shield layer 95. In the manufacturing process of the radio-frequency module 1, the module substrate 90, the electronic components, the sealing member 83, the laminate resin layer 81, and the sealing member 82 are stacked in this order from the negative side of the z-axis, thereby forming an in-process workpiece. Subsequently, the in-process workpiece is polished from the positive side of the z-axis until the top surface of the acoustic wave filter 11 is exposed. After this polishing, the shield layer 95 is formed from the positive side of the z-axis. As a result, in the radio-frequency module 1 as a finished product, the side surface of the acoustic wave filter 11 is in contact with the major surface 81a of the laminate resin layer 81. This structure improves the heat dissipation of the acoustic wave filter 11. The top surface of each of the electronic components other than the acoustic wave filter 11 may be in contact with the shield layer 95.

As illustrated in FIG. 2A, the switch 61 is disposed on the major surface 90a adjacent to the acoustic wave filter 11, and the inductor 51 is disposed on the major surface 90a adjacent to the switch 61. Between the acoustic wave filter 11 and the switch 61, the major surfaces 90a and 81a are in contact with each other. Between the switch 61 and the inductor 51, the laminate resin layer 81 has an opening 85, and the sealing member 82 is disposed between the switch 61 and the inductor 51 and between the major surfaces 90a and 81a.

Since the major surfaces 90a and 81a are in contact with each other between the acoustic wave filter 11 and the switch 61, the sealing member 82 is prevented from being introduced into the gap between the IDT electrode 150 and the major surface 90a in the acoustic wave filter 11. This structure suppresses the degradation of the bandpass characteristic of the acoustic wave filter 11. Since the laminate resin layer 81 has the opening 85 between the switch 61 and the inductor 51, the sealing member 82 is introduced through the opening 85 into the space between the switch 61 and the inductor 51 and between the major surfaces 90a and 81a. This structure improves the fixing strength of the switch 61 and the inductor 51 on the module substrate 90, thereby improving reliability, and the mechanical strength of the radio-frequency module 1 is improved. Since providing a single opening 85 between the switch 61 and the inductor 51 is sufficient to introduce the sealing member 82 into the space between the switch 61 and the inductor 51 and the major surface 90a, the radio-frequency module 1 can be reduced in size.

The major surfaces 90a and 81a are not in contact with each other between the switch 61 and the inductor 51. As such, the sealing member 82 is disposed between the switch 61 and the inductor 51 with the laminate resin layer 81 not interposed therebetween, thereby reducing the space between the switch 61 and the inductor 51. From this perspective as well, the radio-frequency module 1 can be reduced in size.

As illustrated in FIG. 2A, openings 85 may be provided (1) between the switch 61 and the inductor 52, (2) between the inductor 53 and the low-noise amplifier 41, and (3) between the inductor 54 and the low-noise amplifier 41. This structure improves the mechanical strength of the radio-frequency module 1 and enables the size reduction of the radio-frequency module 1.

The inductor 54 and the low-noise amplifier 41 each have a rectangular shape having a long edge and a short edge when the major surface 90a is viewed in plan view. In this case, the opening 85 is positioned along at least one of the long edge of the inductor 54 and the long edge of the low-noise amplifier 41. This structure facilitates introduction of the sealing member 82 into the space between the inductor 54 and the low-noise amplifier 41 and the major surface 90a.

The laminate resin layer 81 may have openings 85 positioned along each of the four outer edges of the low-noise amplifier 41 in the plan view described above. This structure facilitates introduction of the sealing member 82 into the space between the low-noise amplifier 41 and the major surface 90a.

The low-noise amplifier 41 is desirably joined to the major surface 90a via multiple bumps, and the opening 85 is desirably positioned so as not to oppose, among these bumps, the bumps disposed close to an outer edge of the low-noise amplifier 41, the outer edge opposing the inductor 53. Since the bumps do not block introduction of the sealing member 82 through the opening 85 into the space between the low-noise amplifier 41 and the major surface 90a, this structure facilitates the introduction of the sealing member 82 into the space between the low-noise amplifier 41 and the major surface 90a.

The opening 85 is desirably positioned along the farthest outer edge of the inductor 53 from the acoustic wave filter 21 among the four outer edges of the inductor 53 in the plan view described above. This structure prevents the sealing member 82 from reaching the acoustic wave filter 21 while the sealing member 82 is introduced through the opening 85 into the space between the inductor 53 and the major surface 90a.

### 4. Mounting Configuration of Radio-Frequency Module 1A

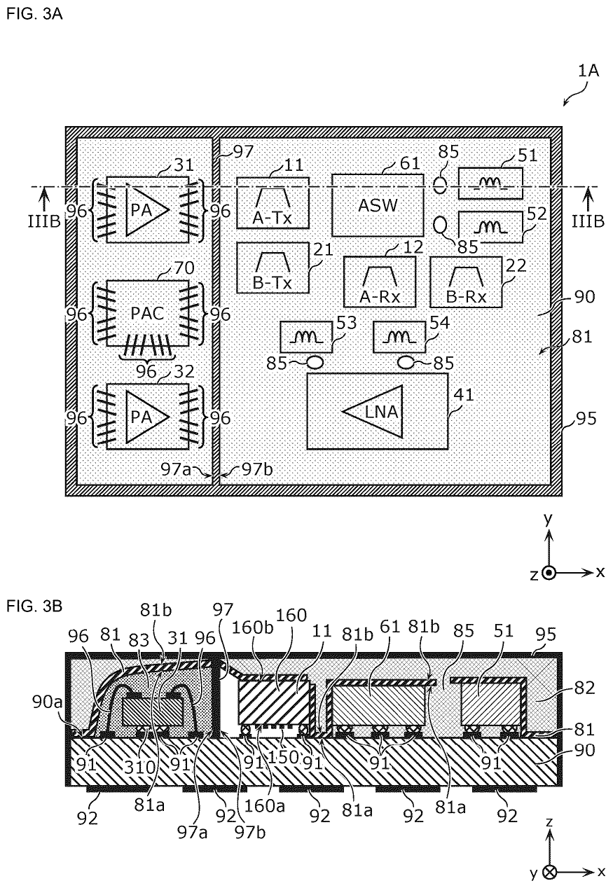

FIGS. 3A and 3B are a plan view and a sectional view of a radio-frequency module 1A according to a modification of the embodiment. FIG. 3A is a cutaway view of the major surface 90a of the module substrate 90 as viewed from the positive side of the z-axis. FIG. 3B is a sectional view taken along line IIIB-IIIB in FIG. 3A.

For ease of understanding the positional relationship between electronic components, FIG. 3A omits illustration of the sealing member 83, which covers the power amplifiers 31 and 32 and the PA control circuit 70, the sealing member 82, which covers the electronic components, and the shield layer 95, which covers the sealing member 82.

The radio-frequency module 1A includes the acoustic wave filters 11, 12, 21, and 22, the power amplifiers 31 and 32, the low-noise amplifier 41, the switches 61 and 62, the inductors 51, 52, 53, and 54, the PA control circuit 70, the antenna connection terminal 100, the radio-frequency input terminals 110 and 120, the radio-frequency output terminal 130, the module substrate 90, the laminate resin layer 81, the sealing members 82 and 83, the shield layer 95, the planar electrodes 91, the external connection electrode 92, the bonding wires 96, and a metal shield plate 97. The radio-frequency module 1A according to the present modification differs from the radio-frequency module 1 according to the embodiment in that the metal shield plate 97 is included. The following describes the radio-frequency module 1A according to the present modification with a main focus on configurational features different from the radio-frequency module 1 according to the embodiment, and descriptions of the same configurational features as the radio-frequency module 1 according to the embodiment will not be repeated.

The laminate resin layer 81 has the major surface 81a (the second major surface) and the major surface 81b (the third major surface) that oppose each other, as illustrated in FIG. 3B. The major surface 81a is in contact with the major surface 90a, the sealing member 83, the acoustic wave filters 11, 12, 21, and 22, the low-noise amplifier 41, the switch 61, and the inductors 51 to 54. The laminate resin layer 81 is not in contact with the power amplifiers 31 and 32, the PA control circuit 70, or the bonding wires 96. In the present modification, the laminate resin layer 81 covers electronic components other than the power amplifiers 31 and 32 and the PA control circuit 70.

The sealing member 82 is an example of a second sealing member. The sealing member 82 is disposed in contact with the major surface 81b of the laminate resin layer 81. The sealing member 82 differs from the laminate resin layer 81 in at least one of a shape and physical properties.

The sealing member 83 is an example of a first sealing member. The sealing member 83 is disposed in contact with the power amplifiers 31 and 32, the PA control circuit 70, and the bonding wires 96, but not in contact with the acoustic wave filter 11, 12, 21, or 22. The sealing member 83 differs from the laminate resin layer 81 and the sealing member 82 in at least one of a shape and physical properties.

The metal shield plate 97 is disposed upright on the major surface 90a between the acoustic wave filter 11 and the sealing member 83. As illustrated in FIG. 3A, in the present modification, the metal shield plate 97 is disposed upright on the major surface 90a in the y-axis direction between the power amplifiers 31 and 32 and the PA control circuit 70, and the acoustic wave filters 11, 12, 21, and 22, the low-noise amplifier 41, the switch 61, and the inductors 51 to 54. The metal shield plate 97 has a side surface 97a (a first side surface) and a side surface 97b (a second side surface) that are opposite surfaces. As illustrated in FIG. 3B, the side surface 97a is in contact with the sealing member 83, while the side surface 97b opposes the acoustic wave filter 11 with a gap interposed therebetween.

The following describes an example of the manufacturing process of the radio-frequency module 1A.

(1) First, on the module substrate 90 on which the electronic components are mounted, the metal shield plate 97 is disposed upright on the major surface 90a between the power amplifier 31 and the acoustic wave filter 11.

(2) Next, liquid, gel, or powder epoxy resin is applied to the power amplifiers 31 and 32 and the PA control circuit 70, and heat is applied to melt the epoxy resin, thereby forming the sealing member 83 to cover the power amplifiers 31 and 32 and the PA control circuit 70. The molten epoxy resin does not reach the acoustic wave filter 11, 12, 21, or 22, because the molten epoxy resin is blocked by the metal shield plate 97.

(3) Next, a sheet of laminate resin is placed on the entire major surface 90a, powder epoxy resin is applied to the sheet of laminate resin, and heat is applied to soften the sheet of laminate resin and melt the powder epoxy resin, thereby bonding the sheet of laminate resin (the laminate resin layer 81) and the molten epoxy resin (the sealing member 82).

As a result of the manufacturing process described above, the power amplifiers 31 and 32, the PA control circuit 70, and the bonding wires 96 are in contact with the sealing member 83 and are not in contact with the laminate resin layer 81 or the metal shield plate 97. In the region in which the power amplifiers 31 and 32 and the PA control circuit 70 are disposed, the major surface 81a of the laminate resin layer 81 is in contact with the sealing member 83, and the major surface 81b is in contact with the sealing member 82. By contrast, in the region in which the acoustic wave filters 11, 12, 21, and 22 are disposed, the major surface 81a of the laminate resin layer 81 is in contact with the acoustic wave filters 11, 12, 21, and 22, and the major surface 81b is in contact with the sealing member 82. In the region in which the metal shield plate 97 is disposed, the laminate resin layer 81 is in contact with the metal shield plate 97 at a boundary between the metal shield plate 97 and the shield layer 95.

In the manufacturing process according to the present embodiment, the bonding wires 96 are not brought into contact with the laminate resin layer 81, but instead are brought into contact with the sealing member 83 in a molten state. Accordingly, the force applied to the bonding wires 96 by the sealing member 83 is relatively small. As a result, the bonding wires 96 are not deformed, so the reliability of the connection between the power amplifier 31 and the planar electrodes 91 is not degraded.

As a result of the manufacturing process, a gap is formed, in place of the sealing member 82, between the metal shield plate 97 and the acoustic wave filter 11 and between the major surface 90a and the laminate resin layer 81.

This structure prevents the sealing member 82 from being introduced into the gap between the IDT electrode 150 and the major surface 90a, and suppresses heat transfer from the power amplifier 31 to the acoustic wave filter 11 due to the gap formed between the metal shield plate 97 and the acoustic wave filter 11. This structure suppresses the characteristic degradation of the acoustic wave filter 11.

### 5. Configuration of Collective Board 200

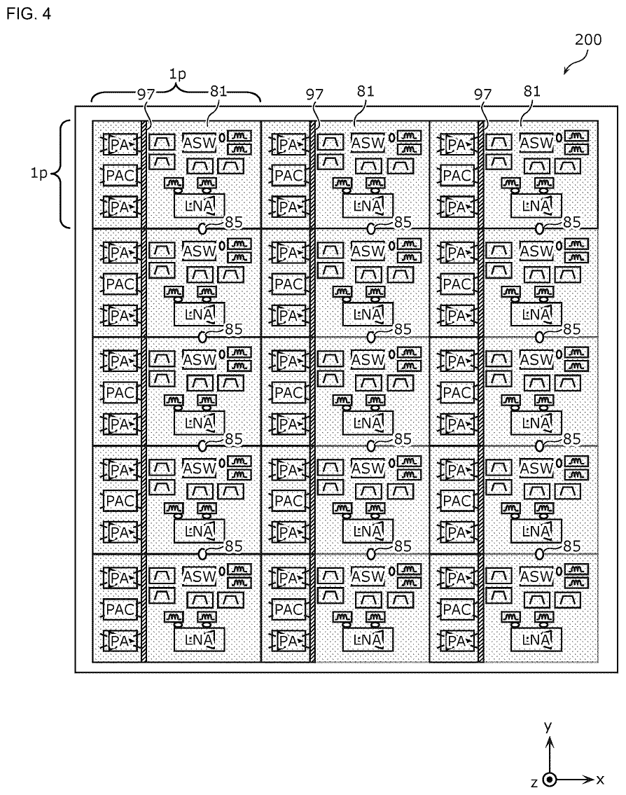

Next, the configuration of a collective board 200 fabricated through the manufacturing process of the radio-frequency module 1A according to the present modification will be described. FIG. 4 is a plan view of the collective board 200 formed through the manufacturing process of the radio-frequency module 1A according to the modification of the embodiment. FIG. 4 illustrates a cutaway view of a major surface of the collective board 200 viewed from the positive side of the z-axis. For ease of understanding the positional relationship between electronic components, FIG. 4 omits illustration of the sealing members 82 and 83. In FIG. 4, each electronic component is labeled with a corresponding reference label, but the actual electronic components are not necessarily labeled with such reference labels.

As illustrated in FIG. 4, the collective board 200 is formed by collectively forming, on a single wafer (the mother substrate of the module substrate 90), multiple in-process workpieces 1p fabricated in the manufacturing process of the radio-frequency module 1A.

In the manufacturing process of the radio-frequency module 1A, first, the electronic components are mounted on a wafer.

Next, on the wafer on which the electronic components are mounted, the metal shield plate 97 is disposed upright on the major surface 90a between the power amplifier 31 and the acoustic wave filter 11. Specifically, the metal shield plate 97 extending from one end to the other end of the wafer in the y-axis direction is disposed upright on the major surface 90a between the power amplifier 31 and the acoustic wave filter 11.

Next, liquid, gel, or powder epoxy resin is applied to the power amplifiers 31 and 32 and the PA control circuit 70, and heat is applied to melt the epoxy resin, thereby covering the power amplifiers 31 and 32 and the PA control circuit 70 with the epoxy resin. The molten epoxy resin (the sealing member 83 in the radio-frequency module 1A) does not reach the acoustic wave filter 11, 12, 21, or 22, because the molten epoxy resin is blocked by the metal shield plate 97.

Next, a sheet of laminate resin is placed on the entire major surface 90a.

Next, an opening 85 is formed at a predetermined location of the laminate resin sheet. Specifically, for example, a laser beam is radiated onto a predetermined position of the laminate resin sheet to form the opening 85.

Next, the sealing member 82 is disposed on the entire region of the wafer on which the laminate resin sheet is placed. Specifically, powder sealing resin, which is a precursor of the sealing member 82, is applied over the entire region of the wafer from the positive side of the z-axis. Thus, the opening 85 functions as an anchor. By allowing the second sealing member 82 to flow through the opening 85 and adhere directly to the first major surface 90a, the adhesion strength of the multi-layer sealing structure is improved, preventing the laminate resin layer 81 from peeling or delaminating from the module substrate 90 due to thermal stress or physical shock.

Next, the wafer on which the electronic components, the laminate resin sheet, and the sealing resin are disposed is subjected to a heat treatment. As a result of the heat treatment, the laminate resin layer 81 is bonded to the sealing member 83 and the acoustic wave filter 11, and the sealing member 82 is introduced through the opening 85 into the spaces between the predetermined electronic components. In this manner, the collective board 200 illustrated in FIG. 4 is fabricated.

Finally, the collective board 200 is singulated into in-process workpieces 1p. Specifically, for example, the collective board 200 is cut into individual in-process workpieces 1p with a dicing machine.

The manufacturing process of the radio-frequency module 1A enables a single metal shield plate 97 to be placed for multiple in-process workpieces 1p, rather than placing a single metal shield plate 97 for each in-process workpiece 1p. In this manner, while the manufacturing process is simplified, the degradation of the bandpass characteristic of the acoustic wave filter is suppressed, and the degradation of the reliability of the connection of electronic components connected to the module substrate with bonding wires can be suppressed.

### 6. Effects

As described above, the radio-frequency module 1 according to the present embodiment includes the module substrate 90 having the major surface 90a, the acoustic wave filter 11 disposed on the major surface 90a, the first electronic component disposed on the major surface 90a, the bonding wire 96 connecting the major surface 90a to the first electronic component, the sealing member 83 that is in contact with the first electronic component and the bonding wire 96 and is not in contact with the acoustic wave filter 11, the laminate resin layer 81 having the major surfaces 81a and 81b that are opposite surfaces, the major surface 81a being in contact with the major surface 90a, the sealing member 83, and the acoustic wave filter 11, and the sealing member 82 disposed in contact with the major surface 81b, the sealing member 82 differing from the laminate resin layer 81 and the sealing member 83.

The bonding wires 96 are brought into contact with the sealing member 83 in a molten state and are covered during the manufacturing process. This configuration suppresses deformation of the bonding wires 96 caused by contact with the laminate resin layer 81. As a result, the reliability of the connection between the first electronic component and the major surface 90a is not degraded.

In an example, in the radio-frequency module 1, the laminate resin layer 81 is not in contact with the first electronic component or the bonding wire 96.

The bonding wire 96 is not in contact with the laminate resin layer 81. This configuration prevents deformation of the bonding wires 96 caused by contact with the laminate resin layer 81.

In an example, in the radio-frequency module 1, the acoustic wave filter 11 includes the piezoelectric substrate 160 having the major surfaces 160a and 160b that are opposite surfaces and also includes the IDT electrode 150 disposed on the major surface 160a. The IDT electrode 150 opposes the major surface 90a with a gap interposed between the IDT electrode 150 and the major surface 90a.

This configuration suppresses the degradation of the bandpass characteristic of the acoustic wave filter 11.

In an example, in the radio-frequency module 1, a corner portion, a side surface of the piezoelectric substrate 160 meeting the major surface 160b at the corner portion, is directly in contact with the sealing member 82, with the laminate resin layer 81 not interposed between the corner portion and the sealing member 82.

The acoustic wave filter 11 is fixed to the module substrate 90 only by bumps, since a gap needs to be formed between the IDT electrode 150 and the major surface 90a. In contrast, because corner portions of the acoustic wave filter 11 are directly in contact with the sealing member 82, the fixing strength of the acoustic wave filter 11 on the module substrate 90 is improved, thereby increasing reliability, and the mechanical strength of the radio-frequency module 1 is improved.

In an example, the radio-frequency module 1 further includes the shield layer 95 disposed to cover the sealing member 82. The major surface 160b is in contact with the shield layer 95.

This configuration improves the heat dissipation of the acoustic wave filter 11.

In an example, the radio-frequency module 1A according to the modification further includes the metal shield plate 97 disposed upright on the major surface 90a between the acoustic wave filter 11 and the sealing member 83. The metal shield plate 97 has the side surfaces 97a and 97b that are opposite surfaces. The side surface 97a is in contact with the sealing member 83. The side surface 97b opposes the acoustic wave filter 11 with a gap interposed between the side surface 97b and the acoustic wave filter 11.

Because the metal shield plate 97 is provided, the sealing member 83 is not in contact with the acoustic wave filter 11, and a gap is formed between the metal shield plate 97 and the acoustic wave filter 11, and between the major surface 90a and the laminate resin layer 81. The gap (or void space) is maintained between the first sealing member 83 and the acoustic wave filter 11. This gap ensures that the vibration of the IDT electrodes on the acoustic wave filter is not dampened by the resin material. The first sealing member 83 may be dispensed with a controlled viscosity such that it encapsulates the first electronic component 31 but does not flow onto the acoustic wave filter 11. This configuration suppresses the degradation of the reliability of the connection between the first electronic component and the major surface 90a, as well as suppressing the characteristic degradation of the acoustic wave filter 11.

The communication device 4 according to the present embodiment includes the RFIC 3 configured to process a radio-frequency signal and the radio-frequency module 1 configured to transfer the radio-frequency signal between the RFIC 3 and the antenna 2.

This configuration enables the communication device 4 to achieve the same effects as the radio-frequency module 1.

### OTHER EMBODIMENTS

The radio-frequency module and the communication device according to the present disclosure have been described by using the embodiment and modification, but the radio-frequency module and the communication device according to the present disclosure are not limited to the embodiment and modification. The present disclosure also embraces other embodiments implemented as any combination of the constituent elements of the embodiment and modification, other modifications obtained by making various modifications to the embodiment and modification that occur to those skilled in the art without departing from the scope of the present disclosure, and various devices including the radio-frequency module according to the present disclosure.

For example, in the circuit configuration of the radio-frequency module according to the embodiment and modification described above, other circuit elements and wires may be inserted in the paths connecting the circuit elements and signal paths that are illustrated in the drawings.

The present invention can be used as a radio-frequency module provided at the front-end in a wide variety of communication devices such as mobile phones.

What is claimed is:

1. A radio-frequency module comprising:
a module substrate having a first major surface;
a first acoustic wave filter disposed on the first major surface;
a first electronic component disposed on the first major surface;
a bonding wire connecting the first major surface to the first electronic component;
a first sealing member encapsulating the first electronic component and the bonding wire and being spaced from the first acoustic wave filter;
a laminate resin layer having a second major surface and a third major surface that are opposite surfaces, the second major surface being in contact with the first major surface, the first sealing member, and the first acoustic wave filter; and
a second sealing member disposed in contact with the third major surface, the second sealing member differing in material property from the laminate resin layer and the first sealing member.

2. The radio-frequency module according to claim 1, wherein
the laminate resin layer is entirely separated from the first electronic component and the bonding wire.

3. The radio-frequency module according to claim 2, wherein the separation is provided by the first sealing member.

4. The radio-frequency module according to claim 1, wherein
the first acoustic wave filter includes
a piezoelectric substrate having a fourth major surface and a fifth major surface that are opposite surfaces, and
a first interdigital transducer (IDT) electrode disposed on the fourth major surface, and
the first IDT electrode opposes the first major surface with a gap interposed between the first IDT electrode and the first major surface.

5. The radio-frequency module according to claim 4, wherein
a corner portion, a side surface of the piezoelectric substrate meeting the fifth major surface at the corner portion, is in direct contact with the second sealing member, through an opening in the laminate resin layer between the corner portion and the second sealing member.

6. The radio-frequency module according to claim 4, further comprising:
a shield layer covering the second sealing member, wherein
the fifth major surface is in thermal contact with the shield layer.

7. The radio-frequency module according to claim 1, further comprising:
a metal shield plate extending vertically from the first major surface between the first acoustic wave filter and the first sealing member.

8. The radio-frequency module according to claim 7, wherein
the metal shield plate has a first side surface and a second side surface that are opposite surfaces,
the first side surface is in contact with the first sealing member, and
the second side surface opposes the first acoustic wave filter with a gap interposed between the second side surface and the first acoustic wave filter.

9. The radio-frequency module according to claim 1, wherein the first sealing member has a different elastic modulus than the laminate resin layer.

10. The radio-frequency module according to claim 1, further comprising:
a second electronic component disposed on the first major surface; and
an inductor disposed on the first major surface adjacent to the second electronic component, wherein the laminate resin layer includes an opening located between the second electronic component and the inductor.

11. The radio-frequency module according to claim 1, wherein the second sealing member extends through the opening in the laminate resin layer and contacts the first major surface between the second electronic component and the inductor.

12. The radio-frequency module according to claim 1, further comprising at least one long bump connecting the first electronic component to the first major surface.

13. A communication device comprising:
a signal processing circuit configured to process a radio-frequency signal; and
the radio-frequency module according to claim 1, the radio-frequency module being configured to transfer the radio-frequency signal between the signal processing circuit and an antenna.

14. A method of manufacturing a radio-frequency module, the method comprising:
mounting a first acoustic wave filter and a first electronic component on a first major surface of a module substrate;
connecting the first electronic component to the module substrate via a bonding wire;
applying a first sealing member in a molten state to encapsulate the first electronic component and the bonding wire without contacting the first acoustic wave filter;
curing the first sealing member;
placing a solid laminate resin layer over the first major surface such that the laminate resin layer contacts the first sealing member and the first acoustic wave filter; and
applying a second sealing member over the laminate resin layer.

15. The method according to claim 14, further comprising forming an opening in the laminate resin layer at a position between two electronic components.

16. The method according to claim 15, wherein applying the second sealing member includes causing a portion of the second sealing member to flow through the opening to contact the first major surface of the module substrate.

17. The method according to claim 14, wherein mounting the first electronic component includes using long bumps.

18. The method according to claim 14, wherein the first sealing member has a different elastic modulus than the laminate resin layer.
